(19) United States
(12) Patent Application Publication
(10) Pub. No.: US 2023/0047515 A1
(43) Pub. Date: Feb. 16, 2023

(54) HEAT MITIGATION FOR REARVIEW ASSEMBLY

(71) Applicant: GENTEX CORPORATION, Zeeland, MI (US)

(72) Inventors: Kevin P. Drummond, Grand Rapids, MI (US); Steven J. Veenman, Hudsonville, MI (US); Richard T. Fish, Hudsonville, MI (US)

(73) Assignee: GENTEX CORPORATION, Zeeland, MI (US)

(21) Appl. No.: 17/882,079

(22) Filed: Aug. 5, 2022

Related U.S. Application Data
(60) Provisional application No. 63/230,116, filed on Aug. 6, 2021.

(51) Int. Cl. B60R 1/02; H05K 7/20; H04N 5/225; B60R 1/12; H05K 1/02

(52) U.S. Cl. CPC B60R 1/02; H05K 7/2039; H04N 5/22521; B60R 1/12; H05K 1/0203; B60R 2001/1253; B60R 2001/1215

(57) ABSTRACT

A system for controlling temperatures within a rearview assembly may comprise a rearview assembly having a housing defining an opening and at least one of a display element and an electro-optic element disposed in the opening; and an in-cabin monitoring system comprising at least one printed circuit board; an imager disposed on one of the at least one printed circuit boards, an image signal processor in communication with the imager, at least one light source, and at least one heat spreader positioned within the housing. The heat spreader may be stamped aluminum. The imager may be at a distance from the at least one light source.

### CROSS REFERENCE TO RELATED APPLICATIONS

This application claims the benefit of and priority to U.S. Provisional Patent Application No. 63/230,116, filed on Aug. 6, 2021, entitled “Heat Mitigation for Rearview Assembly Having Integrated Cabin Monitoring Features,” the entire disclosure of which is hereby incorporated herein by reference.

### FIELD OF THE DISCLOSURE

This disclosure relates generally to heat mitigation for rearview assemblies, and in particular, to heat mitigation in rearview assemblies that have in-cabin monitoring systems.

### BACKGROUND

New automotive regulations in certain regions, such as the EU, will soon require monitoring of vehicle drivers and occupants for safety reasons. Rearview assemblies are positioned in an advantageous location for in-cabin monitoring systems since the rearview assemblies have a line of sight to most of the cabin, thereby making the integration of the in-cabin monitoring system into the rearview assembly desirable.

Most in-cabin monitoring systems consist of infrared (IR) illumination paired with a camera and an image signal processor (ISP), along with power and communications infrastructure. The electronic components required for these in-cabin monitoring systems produce a significant amount of heat, which creates a challenging thermal problem. At elevated temperatures, electro-optic elements and/or display elements of rearview assemblies may not operate properly. Furthermore, it is important to keep the housing and exterior components of the rearview assembly, such as display element and/or electro-optic elements from reaching a temperature at which they could cause discomfort to a user attempting to adjust the rearview assembly.

### SUMMARY

According to an aspect, a system for controlling temperatures within a rearview assembly may comprise a rearview assembly having a housing defining an opening and at least one of a display element and an electro-optic element disposed in the opening; and an in-cabin monitoring system comprising at least one heat spreader positioned within the housing; at least one printed circuit board disposed on the heat spreader; at least one light source disposed on one of the printed circuit boards; an imager disposed on one of the at least one printed circuit boards; and an image signal processor in communication with the imager. The imager may be disposed at a distance from the at least one light source. The heat spreader may be stamped aluminum. The imager may be at a distance from the at least one light source.

The heat spreader may be positioned between the printed circuit board and the housing of the rearview assembly and may be configured to transmit heat directly to the housing. The heat spreader may be positioned between the printed circuit board and a display element. The heat spreader may be positioned between the printed circuit board and an electro-optic element. The image signal processor may be configured to process images captured by the imager as part of an in-cabin monitoring system. The at least one light source may comprise a first infrared light emitting diode configured to emit light in a first direction and a second infrared light emitting diode configured to emit light in a second direction different from the first direction. The heat spreader may define at least one opening, and at least one of imager and the light source extends into or through openings defined by heat spreader. The heat spreader may support at least one of the printed circuit boards. The imager may be secured to the heat spreader.

### BRIEF DESCRIPTION OF THE DRAWINGS

FIG. 1A illustrates a front perspective view of an embodiment of a rearview assembly in accordance with this disclosure;

FIG. 1B illustrates a first interior view of the rearview assembly of FIG. 1, showing a printed circuit board within the housing;

FIG. 1C illustrates a second interior view of the rearview assembly of FIG. 1 showing the heat spreader within the housing;

FIG. 2 illustrates a top cross-sectional view of an embodiment of a rearview assembly in accordance with this disclosure;

FIG. 3A illustrates a perspective view of a first side of a printed circuit board and a heat spreader in accordance with this disclosure;

FIG. 3B illustrates a perspective view of a second side of the printed circuit board of FIG. 3A;

FIG. 4 illustrates one embodiment of current practices of thermal mitigation in a rearview assembly;

FIG. 5 illustrates an embodiment of a rearview assembly in accordance with this disclosure;

FIG. 6 illustrates another embodiment of a rearview assembly in accordance with this disclosure;

FIG. 7A illustrates another embodiment of a rearview assembly in accordance with this disclosure;

FIG. 7B illustrates another embodiment of a rearview assembly in accordance with this disclosure;

FIG. 8 illustrates another embodiment of a rearview assembly in accordance with this disclosure;

FIG. 9 illustrates another embodiment of a rearview assembly in accordance with this disclosure; and

FIG. 10 illustrates another embodiment of a rearview assembly in accordance with this disclosure.

### DETAILED DESCRIPTION

Many rearview assemblies for vehicles now integrate other features such as driver monitoring or cabin monitoring directly or partially into the rearview assembly. When these features are included in a rearview assembly, it may necessitate the inclusion of additional components in the rearview assembly. The additional components may generate significant amounts of heat. Therefore, heat mitigation may be an issue that needs to be resolved.

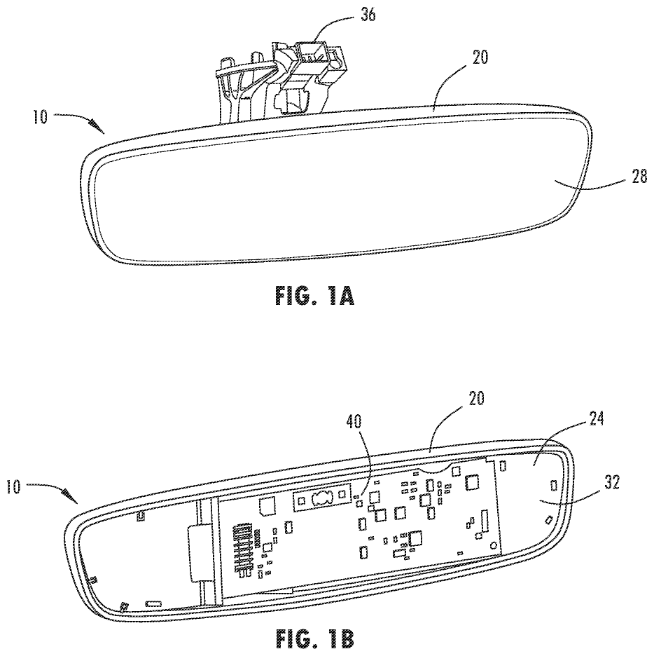

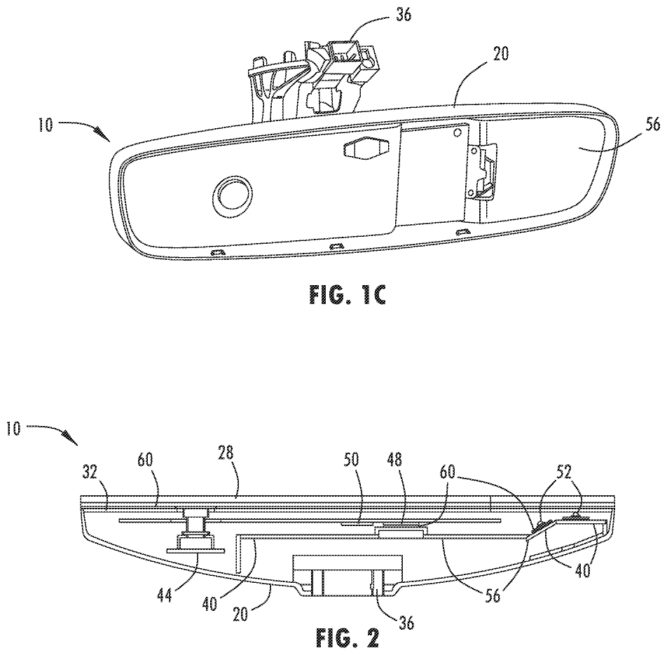

Referring to FIGS. 1A and 1B, a rearview assembly, generally referred to by reference number 10, may be configured to be secured to a vehicle windshield or roof (not shown) via a mount 36. Rearview assembly 10 may comprise a housing 20 defining an opening 24. At least one of a display element, a reflective element, and an electro-optic element 28 on a carrier plate 32 may be disposed to cover opening 24. Rearview assembly 10 may comprise an in-cabin monitoring system 40. In cabin monitoring system may be configured to monitor at least one of a driver of the vehicle, one or more passengers of the vehicle, and the vehicle cabin itself. In-cabin monitoring system 40 may comprise at least one printed circuit board (PCB) 40, an imager 44 disposed on one of the at least one PCBs 40, an image signal processor 48 in communication with imager 44, a memory 50 in communication with image signal processor 48, at least one light source 52, and at least one heat spreader 56, and additional circuitry to drive and communicate with the in-cabin monitoring system 40. In-cabin monitoring system 40 may further comprise at least one power supply (not shown).

Rearview assemblies may provide good locations for in-cabin monitoring systems, as they have clear lines of sight to much of the interior of a vehicle cabin. Including components of in-cabin monitoring system in rearview assembly 10 may make integration of in-cabin monitoring system 40 easier while also giving a cleaner look to the vehicle cabin. However, in-cabin monitoring system components, along with the associated supplemental electronics required to operate in-cabin monitoring system 40, may generate a significant amount of heat. The heat may be sufficient to overheat components within rearview assembly 10. Therefore, heat mitigation measures may need to be undertaken within rearview assembly 10.

To remove heat from the components and reduce the heat load in the in-cabin monitoring system, thermal interface materials (TIMs) 60, such as gap pads, thermal paste, thermal epoxy, and the like, may be placed between some of the components and heat spreader 56. However, these may not be sufficient to prevent overheating of components within rearview assembly 10, and additional measures may need to be taken.

As shown in FIGS. 1B and 1C, at least one PCB 40 and associated components may be disposed within housing 20. Heat spreader 56 may also be disposed within housing 20. Heat spreader 56 may be disposed either between PCB 40 and opening 24 or between PCB 40 and housing 20. In cases in which there is more than one PCB 40, one or more heat spreaders 56 may be disposed between two PCB s 40 and/or between PCB 40 and opening 24 and/or between PCB 40 and housing 20.

The at least one light source 52 may comprise light emitting diodes (LEDs), and in particular, may comprise infrared (IR) LEDs 52. The at least one light source 52 may be capable of illuminating the cabin of the vehicle. In some embodiments, a first light source 52A may be disposed on a first PCB 40A oriented to illuminate a first field of view and a second light source 52B may be disposed on a second PCB 40B and oriented to illuminate a second field of view. First field of view may partially overlap with second field of view. For example, first field of view may illuminate the driver position of the vehicle and the area behind it, while second field of view may illuminate the front passenger position of the vehicle and the area behind it.

Heat spreaders 56 may be used to dissipate heat from the main heat-generating components of in-cabin monitoring system 40, such as light sources 52, image signal processors 48, and other electronics. Heat spreaders 56 may comprise a stamped metal or stamped aluminum heat spreader 56. In some embodiments, heat spreader 56 may be anodized. This may increase the amount of heat removed by heat spreader 56 from PCBs 40 and associated components. Heat spreader 56 may be relatively lightweight. In some embodiments, heat spreader 56 may be generally symmetric. Heavy and/or asymmetric heat spreaders may cause mechanical issues such as vibration, in rearview assemblies. Heat spreader 56 may be manufactured using a simple metal stamping/forming process and, therefore, may be inexpensive.

The stamped metal heat spreader 56 may be bent to specific dimensions to accurately position light sources 52 and imager 44. Heat spreader 56 may also include locating features. This may provide a relatively cheap and simple method for mechanical positioning of the emitters and camera, which is critical for the in-cabin monitoring system 40 features to work properly. The integrated design may also effectively remove heat from light sources 52 and imager 44. This may allow the in-cabin monitoring system 40 to work more efficiently at nominal operating temperatures and to work at high operating temperatures.

Heat spreader 56 may define openings for imager 44 and/or for light sources 52. Imager 44 and/or light sources 52 may extend into or through openings defined by heat spreader 56. The arrangement described above may significantly reduce temperatures on exterior surfaces of rearview assembly 10, allowing temperatures to remain below desired upper temperature thresholds.

Heat spreader 56 may increase the area for heat transfer, thus reducing temperatures of the components. In some embodiments, multiple heat spreaders 56 may be used to keep the heat from the components spread out more uniformly throughout the mirror. In some embodiments, heat spreader 56 may be mounted directly to housing 20 to provide a more direct path for heat removal, transferring heat to the housing for dissipation. Heat spreader 56 may also be used as a mechanical feature of rearview assembly 10 that can provide mechanical stiffness and may be used as a base for attaching components. Since heat spreader 56 may be formed in a variety of shapes, it may be used to help hold at least one of the PCBs in place, thereby directing the at least one light source 52 to the desired area of the vehicle cabin.

Heat spreader 56 may be secured to at least one light source 52, 52A, 52B, and imager 44. Heat spreader 56 may be configured to properly position and direct the at least one light source 52, 52A, 52B and imager 44.

Imager 44 may correspond to a complementary metal-oxide-semiconductor (“CMOS”) image sensor, such as, a CMOS active-pixel sensor (APS) or a charge coupled device (CCD) that can create image data when activated.

Imager 44 may be capable of receiving information about vehicle occupants, including the driver and any passengers. Information may allow the in-cabin monitoring system 40 to monitor such things as driver alertness, gaze location, behavior, and driver readiness for autopilot return of control, driver distraction, driver drowsiness, return of manual vehicle control, occupant detection, passenger posture and behavior, objects left behind in vehicle, and restraint optimization.

Providing a heat spreader 56 having a geometry that allows it to better dissipate heat from problem areas and strategically arranging components in relation to the heat spreader 56 may allow mirror components to remain within their desired temperature ranges while also keeping housing 20 at or below its desired temperature limit. This may allow in-cabin monitoring features to be integrated into rearview assembly while adhering to strict automotive thermal requirements.

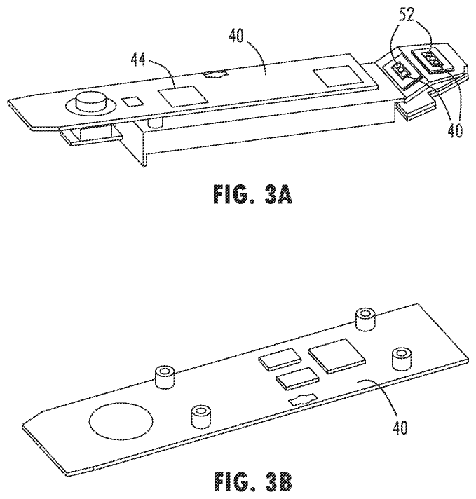

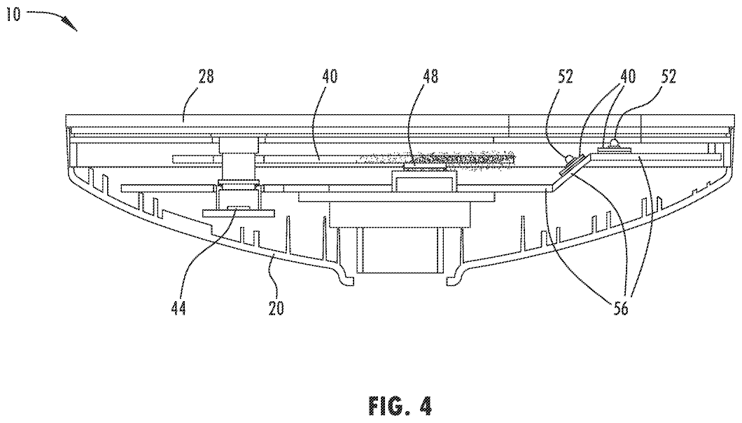

Referring now to FIGS. 3A-10, the stippling in these figures represents areas of elevated temperatures, specifically temperatures over about 110 deg. C. Areas with heavier stippling represent areas in which the temperatures are above about 115 deg. C. As shown in the figures, the at least one light source 52 may be positioned as far from imager 44 as possible while still being positioned appropriately to capture images in the desired fields of view. As shown in FIG. 4, current practice may include locating imager 44 in a central position on PCB 40, while IR LEDs 52 may be at an end of PCB 40. However, in this configuration, some components may become excessively hot.

In some embodiments, the at least one power supply and other heat-generating components may be disposed on one side of one of the at least one PCB 40 and imager 44 may be disposed on an opposite side of the at least one PCB 40. In some embodiments, the at least one power supply and other heat-generating components may be in proximity to or in contact with heat spreader 56. In some embodiments, heat spreader 56 may be disposed between housing 20 and PCB 40.

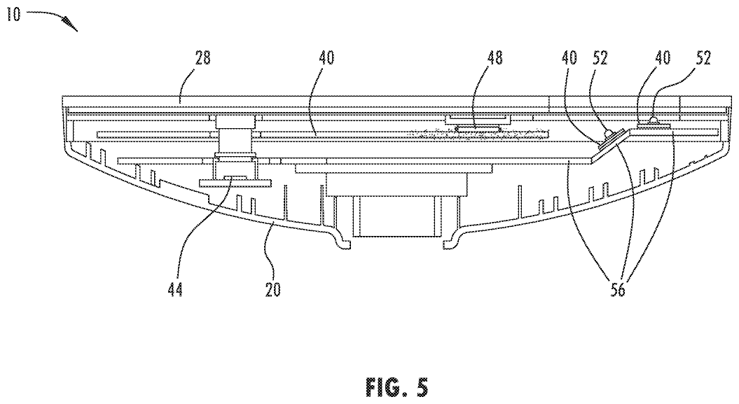

As shown in FIG. 5, in some embodiments, at least two heat spreaders 56 may be used. The at least two heat spreaders 56 may be disposed adjacent to one another and in contact with one another, or there may be a space between the at least two heat spreaders 56. A first heat spreader 56A may be associated with image signal processor 48 while a second heat spreader 56B may be associated with the at least one IR LED 52. This arrangement may allow heat to be distributed more evenly throughout the mirror, and result in a significant decrease in component temperatures over current arrangements, as shown in Table 1.

TABLE 1
Temperatures of components in embodiment
of FIG. 4 and embodiment of FIG. 5

| | Temp in FIG. | Temp in FIG. |
|---|---|---|
| Component | 4 (° C.) | 5 (° C.) |
| Processor | 130 | 115 |
| Memory | 123 | 116 |
| IR LEDs | 123 | 115 |
| Imager | 113 | 107 |
| Image Signal Processor | 116 | 109 |

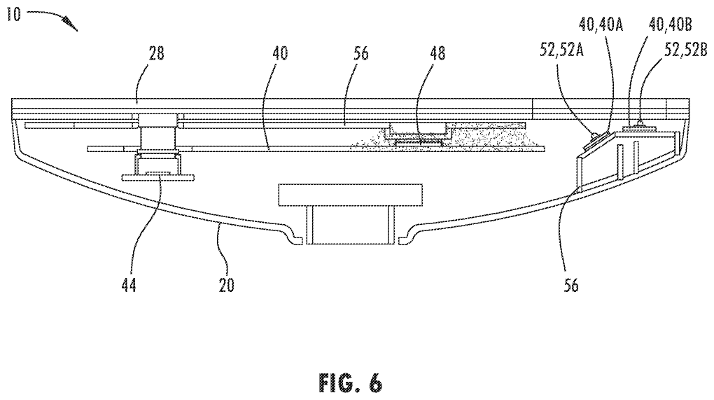

In some embodiments, as shown in FIG. 6, rearview assembly 10 may comprise more than one PCB 40 and IR LEDs 52 may be on a separate PCB 40 from imager 44. A first heat spreader 56A may be associated with processor 48 and a second heat spreader 56B may be disposed proximate the separate PCB 40 holding the IR LEDs 52. Second heat spreader 56B may further be in contact with housing 20 of rearview assembly 10 such as by, for example, being mounted to housing 20.

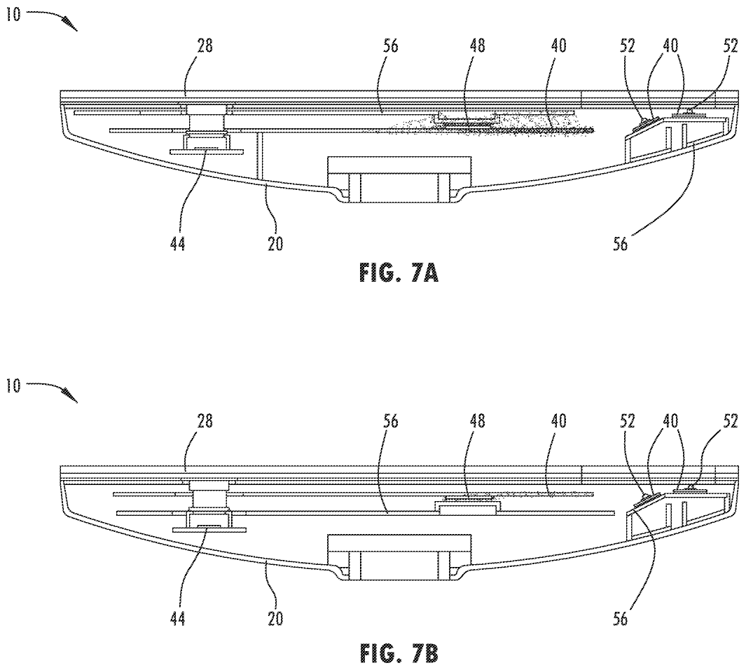

In some embodiments, first heat spreader 56A may be disposed between PCB 40 and display or electro-optic element 28 as shown in FIG. 7A. In some embodiments, first heat spreader 56A may be disposed between PCB 40 and housing 20 as shown in FIG. 7B. Housing 20 provides a larger surface area over which heat can be dissipated than either display element 28 or electro-optic element 28. Also in this arrangement, heat spreader 56 may extend further toward IR LEDs 52 without blocking light from the IR LEDs 52, and it may provide better access to air circulating in housing 20. In some embodiments, a first heat spreader 56A may be disposed proximate to a first side of PCB 40 between PCB 40 and housing 20 and a second heat spreader 56B may be disposed proximate a second side of PCB 40. Second heat spreader 56B may be disposed to be proximate IR LEDs 52 and associated PCB 40, and may be in contact with housing 20. Second heat spreader 56B may be injection molded or may be otherwise secured to housing 20.

IR LEDs 52 and processors 48 may be placed at a distance from imager 44. Furthermore, power supplies and other miscellaneous heat-generating components may be disposed on a first surface of PCB 40 and processor 48 may be disposed on an opposite surface of PCB 40.

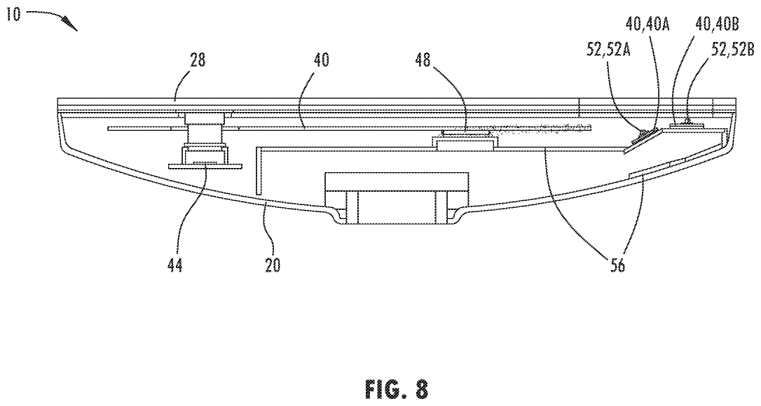

In some embodiments, as shown in FIG. 8, a combined heat spreader 56 may extend along a length of PCB 40 or PCBs 40, and along a portion of housing 20. Heat spreader 56 may be injection molded, clipped to, or otherwise in direct contact with housing 20.

In some embodiments, as shown in FIGS. 3-10, a first light source 52A may be on a first PCB 40A or a first section of PCB 40A and a second light source 52B may be on a second PCB 40B or a second section of PCB 40B. First PCB or section of PCB 40A may be disposed at an angle from second PCB or section of PCB 40B. This may allow better coverage of the vehicle cabin by light sources 52 as each of first and second light sources 52A, 52B may illuminate a different portion of the vehicle cabin; i.e., first light source 52A may illuminate a first portion of the vehicle cabin and second light source 52B may illuminate a second portion of the vehicle cabin. The second portion of the vehicle cabin may be separate from the first portion, or the second portion of the vehicle cabin may partially overlap with the first portion. Heat spreader 56 may be configured to be in proximity to both first PCB or section of PCB 40A and second PCB or section of PCB 40B, and may be configured to have generally the same angle of the PCBs where it is proximate to the PCBs 40A, 40B.

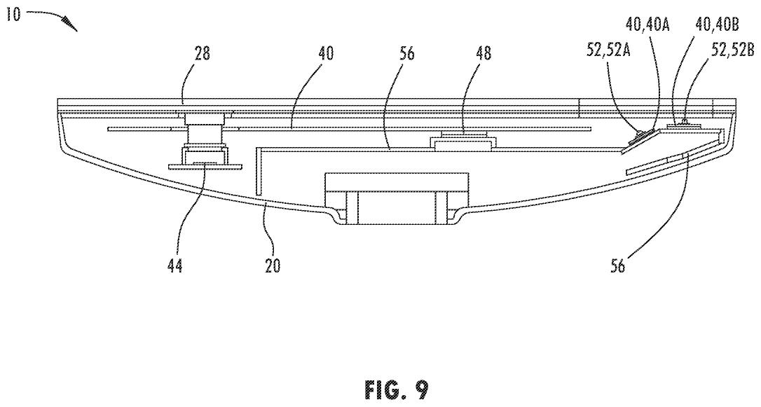

In some embodiments, as shown in FIG. 9, a portion of heat spreader 56 may be in proximity to but not in contact with housing 20. This arrangement may prevent a portion of housing 20 adjacent to heat spreader 56 from overheating or becoming uncomfortably hot to a user's touch.

In some embodiments, as seen in FIGS. 6, 7A, 7B, and 8, heat spreader 56 may be configured to directly contact a rear portion of housing 20 of rearview assembly 10. In some embodiments, heat spreader 56 may be configured to directly contact a plurality of portions of housing 20 of rearview assembly 10.

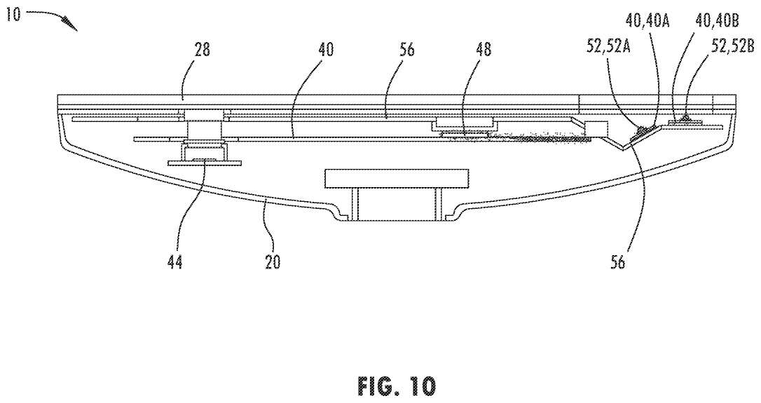

In some embodiments, as shown in FIG. 10, heat spreader 56 may comprise multiple different sections. The sections may abut one another. Each PCB 40A, 40B may be secured to a different section of heat spreader 56.

The above description is considered that of the preferred embodiments only. Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims as interpreted according to the principles of patent law, including the doctrine of equivalents. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts, or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

In this document, relational terms, such as first and second, top and bottom, front and back, left and right, vertical, horizontal, and the like, are used solely to distinguish one entity or action from another entity or action, without necessarily requiring or implying any actual such relationship, order, or number of such entities or actions. These terms are not meant to limit the element which they describe, as the various elements may be oriented differently in various applications. Furthermore, it is to be understood that the device may assume various orientations and step sequences, except where expressly specified to the contrary. It is also to be understood that the specific devices and processes illustrated in the attached drawings and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

It will be understood that any described processes or steps within described processes may be combined with other disclosed processes or steps to form structures within the scope of the present disclosure. The exemplary processes disclosed herein are for illustrative purposes and are not to be construed as limiting. It is also to be understood that variations and modifications can be made on the aforementioned methods without departing from the concepts of the present disclosure, and further it is to be understood that such concepts are intended to be covered by the following claims unless these claims by their language expressly state otherwise.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within at least one of 2% of each other, 5% of each other, and 10% of each other.

1. A system for controlling temperatures within a rearview assembly, comprising:
a rearview assembly having a housing defining an opening and at least one of a display element and an electro-optic element disposed in the opening; and
an in-cabin monitoring system, comprising:
at least one heat spreader positioned within the housing;
at least one printed circuit board disposed on the heat spreader;
at least one light source disposed on one of the printed circuit boards;
an imager disposed on one of the at least one printed circuit boards; and
an image signal processor in communication with the imager;
wherein the imager is disposed at a distance from the at least one light source.

2. The system of claim 1, wherein the heat spreader is positioned between the printed circuit board and the housing of the rearview assembly and configured to transmit heat directly to the housing.

3. The system of claim 2, wherein a portion of the heat spreader abuts an inner surface of the housing.

4. The system of claim 2, wherein a portion of the heat spreader is disposed in close proximity to the housing but not touching the housing.

5. The system of claim 1, wherein the heat spreader is positioned between the printed circuit board and display element.

6. The system of claim 1, wherein the heat spreader is positioned between the printed circuit board and an electro-optic element.

7. The system of claim 1, wherein the image signal processor is configured to process images captured by the imager as part of an in-cabin monitoring system.

8. The system of claim 1, wherein the heat spreader is stamped aluminum.

9. The system of claim 1, wherein the at least one light source comprises a first infrared light emitting diode configured to emit light in a first direction and a second infrared light emitting diode configured to emit light in a second direction different from the first direction.

10. The system of claim 1, wherein the heat spreader defines at least one opening, and wherein at least one of imager and the light source extends into or through openings defined by heat spreader.

11. The system of claim 1, wherein the heat spreader supports at least one of the printed circuit boards.

12. The system of claim 1, wherein the imager is secured to the heat spreader.
